(19) United States
(12) Patent Application Publication
(10) Pub. No.: US 2016/0079389 A1
(43) Pub. Date: Mar. 17, 2016

(54) PREPARATION METHOD OF SEMICONDUCTOR DEVICE

(71) Applicant: Fudan University, Shanghai (CN)

(72) Inventors: Dongping Wu, Shanghai (CN); Peng Xu, Shanghai (CN); Xiangbiao Zhou, Shanghai (CN); Chaochao Fu, Shanghai (CN)

(21) Appl. No.: 14/854,763

(22) Filed: Sep. 15, 2015

(30) Foreign Application Priority Data
Sep. 16, 2014 (CN) 201410472750.9

(51) Int. Cl. H01L 29/66; H01L 21/265; H01L 21/324; H01L 29/10

(52) U.S. Cl. CPC H01L 29/66537; H01L 29/66545; H01L 29/665; H01L 29/1033; H01L 21/265; H01L 21/324

(57) ABSTRACT

The invention presents a preparation method of semiconductor device, form an amorphous region in the semiconductor substrate, then form the source/drain region of the semiconductor device in the semiconductor substrate, the amorphous region can restrain the generation of end-of-range defects of the source/drain region, then can lower well the current leakage between the semiconductor device source/drain region and the semiconductor substrate; besides, after the dummy gate structure is eliminated, form a short channel inhibition region in the channel region; it can restrain the short-channel effect of the semiconductor device and satisfy the requirement of keeping narrowing the feature size of the device.

### FIELD OF TECHNOLOGY

The invention relates to the area of semiconductor manufacture, especially to a preparation method of semiconductor device.

### DESCRIPTION OF RELATED ARTS

As the progress of semiconductor industry and the development of Moore's law, the feature size and depth of MOS (metal-oxide semiconductor) devices continues to shrink, especially into nodes of 65 nanometers or lower, the channel of MOS device is shorter and shorter, short-channel effect (SCE) is worse and worse, the DIBL (drain induction barrier lowering) of source/drain has a serious current leakage.

As the feature size and depth continues to shrink, the source/drain and the source/drain extension region (Source/Drain Extension) are required to be shallow accordingly, the doped junction with a junction depth lower than 100 nm is usually called ultra shallow junction (USJ), the ultra shallow junction can better improve the short-channel effect. Hence, as the feature size of devices is smaller and smaller, the demand of ultra shallow junction is bigger and bigger. To form an ultra shallow junction, pre-implantation and non-crystallization are needed.

Specifically, in the existing technology, usually use gate as mask, use ions such as boron (or BF2), arsenic and so on to be implanted into a semiconductor substrate in turn vertically or at an angle to form an ultra-shallow lightly doped source/drain region and source/drain extent region, and to achieve the formation of ultra shallow junction of the MOS device. This lightly doped drain (LDD) ion implantation technology uses ions such as boron (or BF2), arsenic and so on to be ultra-low energy implanted. This implantation will turn the substrates from crystal to non-crystal, and generate big number of serious defects between non-crystal/crystal interface (usually called end of range defects, EOR Defects). During the following annealing process and activation of semiconductor device, the EOR defects are hard to be repaired by annealing and then cause serious problem: on one hand, the EOR defects will enhance the diffusion of the germanium, boron (or BF2) ions implanted before, and enlarge the short-channel effect, go against the formation of ultra shallow junction; on the other hand, the forming non-crystal layer recrystallized, the EOR defects will dissolve the semiconductor interstitial atoms effectively move towards the device structure surface, it will trigger instantaneous transient-enhanced diffusion (TED), to cause a degeneration of short channel device feature and bigger junction leakage.

Hence, as the device size and performance increase further, there is a growing need to solve the problems of junction current leakage and short-channel effect.

### SUMMARY OF THE INVENTION

The invention aims to provide a preparation method of semiconductor device, which can lower the junction current leakage and short-channel effect at the same time.

To achieve the above aims, the invention provides a preparation method of semiconductor device, and the method comprises the following steps:

Provide a semiconductor substrate, there is an amorphous region formed in the semiconductor substrate, there are a dummy gate structure and a source/drain region formed on the semiconductor substrate, the source/drain region is formed in the amorphous region;

Etch and eliminate the dummy gate structure and expose the channel region of the semiconductor substrate;

Form a short channel inhibition region in the channel region of the semiconductor substrate;

Form a gate structure on the channel region of the semiconductor substrate.

Compared to the existing technology, in a implementation manner of the invention, form an amorphous region in the semiconductor substrate, then form the source/drain region of the semiconductor device in the amorphous region, the formation of the amorphous region can make the source/drain region epitaxial grow under low-temperature environment and realize the doping activation, the low temperature can restrain the implanted ions diffusion in the source/drain region, so the current leakage between the source/drain region and the semiconductor substrate of the semiconductor device can be well lowered; besides, after eliminating the dummy gate structure, form a short channel inhibition region in the channel region, it can restrain the short-channel effect of the semiconductor device and satisfy the requirement of keeping narrowing the feature size of the device.

Further, the amorphous region is formed by implanting ions, and the ions implanted are non-electrically active ions.

Further, the source/drain region is formed by implanting ions, the ions implanted and the ions doped in the substrate are opposite type ions with each other, and the implantation depth of the source/drain region is lower than the implantation depth of the amorphous region.

Further, the short channel inhibition region is formed by implanting ions, the ions implanted and the ions doped in the substrate are same type ions with each other, and the implantation depth of the short channel inhibition region is lower than the implantation depth of the amorphous region.

Compared to the existing technology, the ions implanted of the short channel inhibition region and the source/drain region formed in the implementation manners of the invention are opposite type ions with each other, and the short channel inhibition region can well restrained the short-channel effect happening between the source and drain in the amorphous region as a hindering region.

Further, after the short channel inhibition region is formed, proceed annealing process before forming the gate structure, and the annealing temperature is not higher than 600° C.

The implementation manners of the invention adopt a low temperature not higher than 600° C. to proceed the annealing process, it can prevent the temperature from too high to lead to big scale diffusion of ions in the source/drain region, then prevent the semiconductor device from source/drain region current leakage, then further improve the performance of the forming semiconductor device.

Further, the steps to form the dummy gate structure include:

Form a dummy gate dielectric layer and a dummy gate successively;

Form the source/drain extension region on the two sides of the dummy gate dielectric layer and the dummy gate;

Form sidewall spacers on the two side walls of the dummy gate dielectric layer and dummy gate.

Further, after the source/drain region is formed, before the dummy gate structure is etched and eliminated, form a first interlayer dielectric layer on two sides of the side-wall spacers and the surface of the semiconductor substrate.

Further, after the gate structure is formed, a second interlayer dielectric layer is formed on the surface of the first interlayer dielectric layer and the gate structure.

Further, the temperatures of forming the sidewall spacers, the first interlayer dielectric layer and the second interlayer dielectric layer are all not high than 500° C.

In the same way, the implementation manners of the invention adopt a low temperatures not high than 500° C. to form the sidewall spacers, the first interlayer dielectric layer and the second interlayer dielectric layer, it is also aim at preventing the temperature from too high to lead to big scale diffusion of ions in the source/drain region, then preventing the forming semiconductor device from source/drain region current leakage, then further improving the performance of the forming semiconductor device.

Further, after the second interlayer dielectric layer is formed, proceed annealing process, and the annealing temperature is not higher than 600° C.

Further, etch the second interlayer dielectric layer and the first interlayer dielectric layer to form a via hole, the via hole exposes the surface of the source/drain region and the gate.

Further, form a self-aligned silicide on the surface of the surface of the source/drain region and the gate exposed in the via hole.

Further, proceed annealing process after the self-aligned silicide is formed, the annealing temperature is not higher than 600° C.

The implementation manners of the invention can only use one annealing process after the self-aligned silicide is formed to get more stable performance of the self-aligned silicide after being annealed at the same time of activating the ions of the source/drain extension region, source/drain region and the short channel inhibition region, in the same way, the annealing temperature is not higher than 600° C., it can prevent the forming semiconductor device from source/drain region current leakage, then further improve the performance of the forming semiconductor device.

### BRIEF DESCRIPTION OF THE DRAWINGS

FIG. 1 is the flow chart of the preparation method of semiconductor device of one embodiment of the invention.

FIGS. 2-14 are the diagrammatic cross-section of the semiconductor device during preparation of one embodiment of the invention.

### DETAILED DESCRIPTION OF THE PREFERRED EMBODIMENT

Now describe the preparation method of semiconductor device of the invention structure in more detail combining the figs., which shows the preferred embodiment of the invention, it should be understand the technicians in the art can modify the invention described here and can still get the benefits of the invention. Hence, the description following should be understood to be well known to the technicians in the art and not the limitation to the invention.

To be clear, not all technical features are described. In the following description, the common function and structure are not described in detail, for they will make the invention chaos due to unnecessary details. It should be considered that during any practical embodiments' exploitation, a large number of implementation details should be made to realize the specific target of a developer, such as changing one embodiment to another embodiment according to relative system or relative commercial limitation. Besides, it should be considered that this kind of development work can be complex and time consuming, but it's only routine work for the technicians in the art.

The following paragraphs describe the invention in the way of illustrating in reference to the figs. According to the following description and claims, the advantages and features will be clearer. It needs to be stated that the figs. all adopt very simplified forms and nonstandard ratio, they are only used to assist illustrating the target of the invention's embodiments conveniently and clearly.

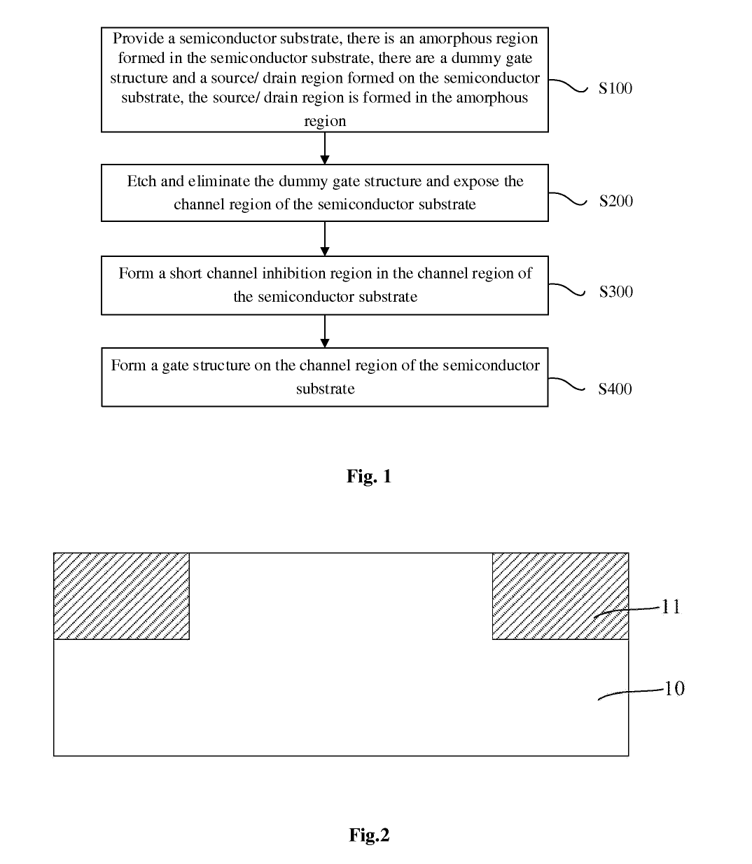

The first implementation manner relates to a preparation method of semiconductor device. The specific flow is shown in FIG. 1, and includes:

S100: Provide a semiconductor substrate, there is an amorphous region formed in the semiconductor substrate, there are a dummy gate structure and a source/drain region formed in the semiconductor substrate, the source/drain region is formed in the amorphous region;

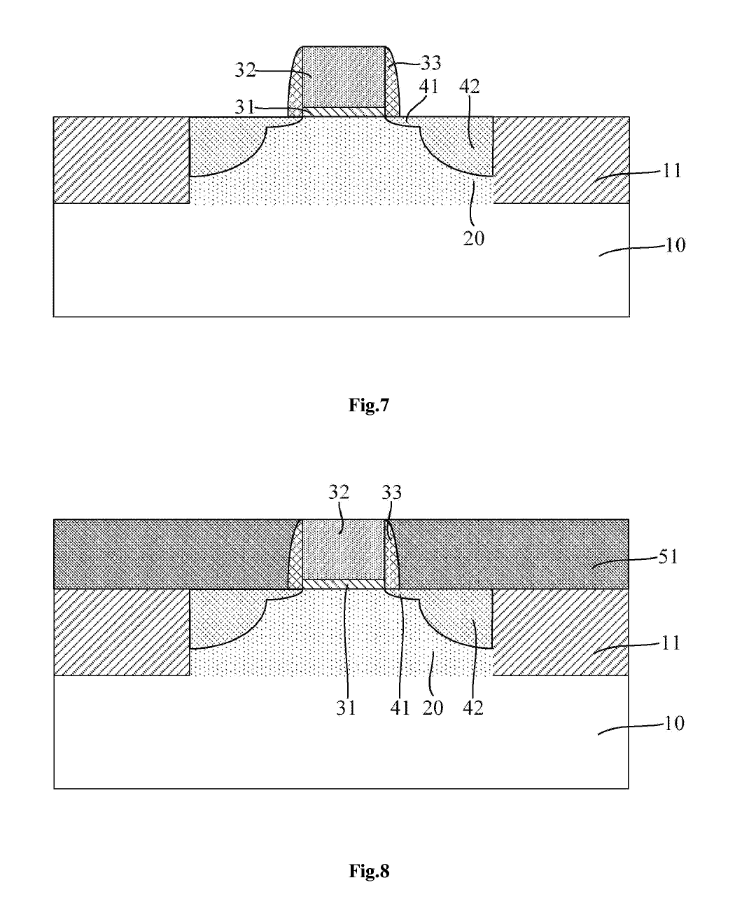

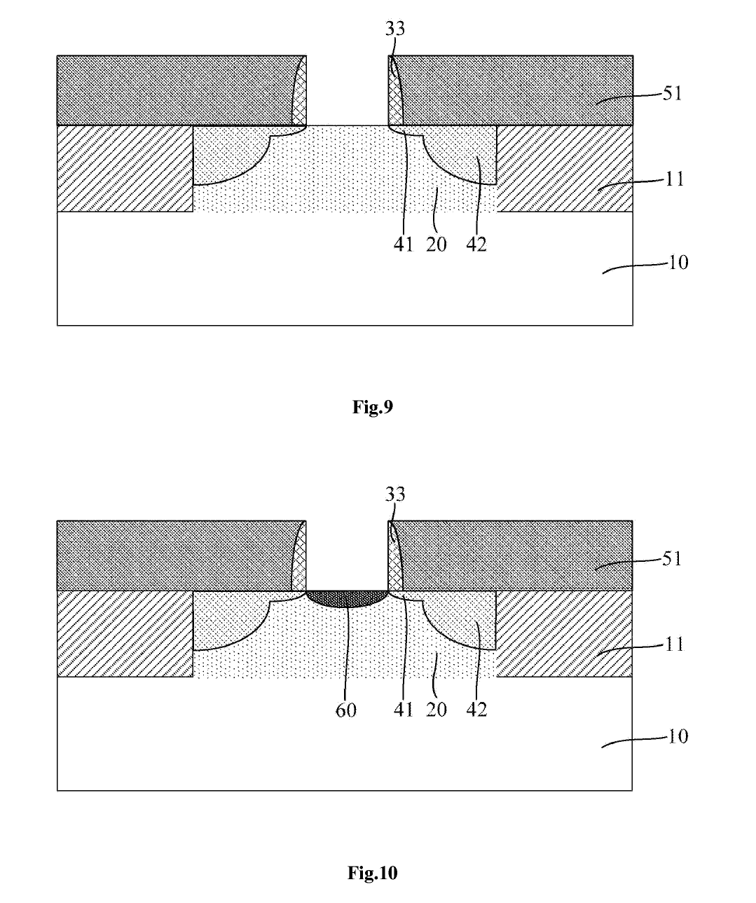

Specifically, refer to FIG. 2˜FIG. 7, in step S100, the step to form the dummy gate structure includes:

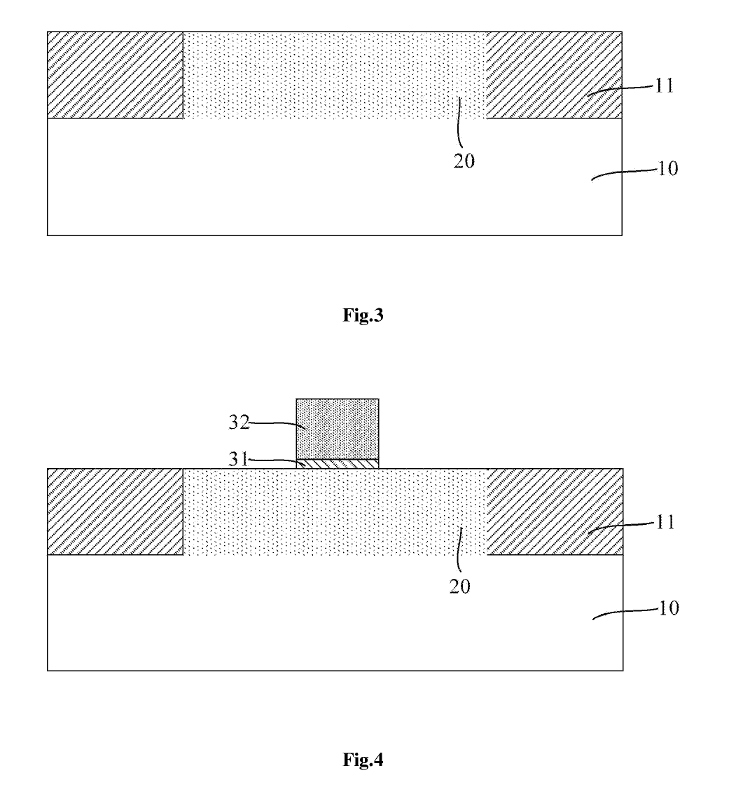

Provide a semiconductor substrate 10, form the amorphous region 20 in the semiconductor substrate 10, wherein, the semiconductor substrate 10 can be common semiconductor material such as monocrystalline silicon, polycrystalline silicon, silicon on insulator, Ge (germanium) or III-V class and so on, there are several shallow trench isolations 11 on the semiconductor substrate 10, the shallow trench isolations 11 can be silicon dioxide, to isolate different semiconductor devices, as shown in FIG. 2; the amorphous region 20 is formed by implanting ions, and the ions implanted are non-electrically active ions, such as the ions implanted are Ge or Si (silicon) and so on; and the depth of amorphous region 20 is bigger than the depth of all the ions formed subsequently, including the depth of the source/drain region, as shown in FIG. 3;

Form a dummy gate dielectric layer 31 and a dummy gate 32 successively on the semiconductor substrate 10, wherein, the material of the dummy gate dielectric layer 31 is silicon dioxide or silicon nitride, it can be formed by the way of chemical vapor deposition to ensure the deposition temperature is not higher than 500° C., and the material of the dummy gate dielectric layer 31 is different from the material of the side-wall spacers formed subsequently, it is in favor of etching process, the material of the dummy gate 32 is polycrystalline silicon or other conductive materials, as shown in FIG. 4;

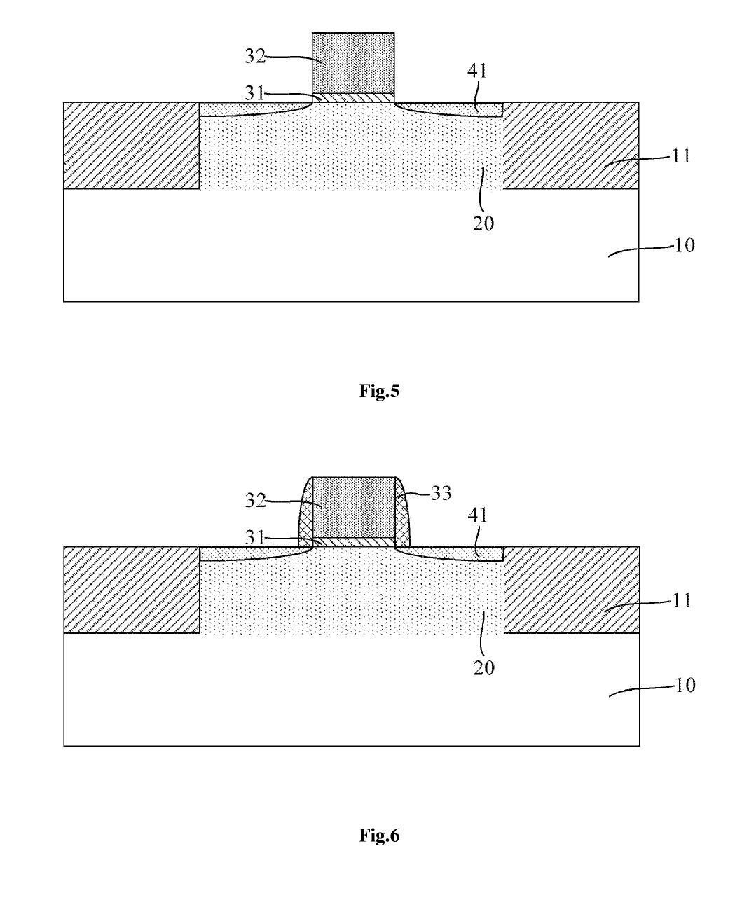

Form a source/drain extension region 41 on the two sides of the dummy gate dielectric layer 31 and dummy gate 32, the source/drain extension region 41 is in the semiconductor substrate 10, and is also in the amorphous region 20, as shown in FIG. 5, the source/drain extension region 41 is formed by implanting ions, for N-type substrate, the ions implanted are B (boron) or BF₂ (boron fluoride), for P-type substrate, the ions implanted are As (arsenic) or P (phosphorus), the implant depth of the source/drain region 41 is usually lower, so the ions implanted usually have lower energy, the energy of the ions implanted usually can be selected according to different requirements.

Form the side-wall spacers 33 on the two side walls of the dummy gate dielectric layer 31 and dummy gate 32, as shown in FIG. 6; the material of side-wall spacers 33 is silicon dioxide, silicon nitride or the combination thereof (such as the combination ONO), for the requirement of following etching, the material of the side-wall spacers 33 and the material of the dummy gate dielectric layer 31 have bigger etching selective ratio, the material of both should be different, in the same way, the side-wall spacers 33 can be formed by the way of chemical vapor deposition to ensure the deposition temperature is not higher than 500° C.;

Form a source/drain region 42 on the two sides of the dummy gate dielectric layer 31 and dummy gate 32, as shown in FIG. 7; the source/drain region 42 is formed by implanting ions, for N-type substrate, the ions implanted are B (boron) or BF₂ (boron fluoride), for P-type substrate, the ions implanted are As (arsenic) or P (phosphorus), that is, its implanted type is the same with the ions implanted of the source/drain extension region 41, the difference is that the depth of the source/drain region 42 is deeper than the source/drain extension region 41, but lower than the amorphous region 20, hence, compared to the ions implanting of the source/drain extension region 41, the source/drain region 42 only has the difference of implanting dose and energy. Form the source/drain extension region 41 and the source/drain region 42 both in the amorphous region 20, it can restrain the diffusion of ions implanted in the source/drain extension region 41 and the source/drain region, and then lower well the current leakage of semiconductor device source/drain region and semiconductor substrate.

S200: etch and eliminate the dummy gate structure and expose the channel region of the semiconductor substrate 10;

Refer to FIG. 8, in the step S200, after the source/drain region 42 is formed, before the dummy gate structure is etched and eliminated, form a first interlayer dielectric layer 51 on the two sides of side-wall spacers 33 and the surface of the semiconductor substrate 10 to protect the surface of the semiconductor substrate 10 and the two sides of side-wall spacers 33 from being damaged by the following etching. The step of forming the first interlayer dielectric layer 51 includes: form the first interlayer dielectric layer 51 on the surface of shallow trench isolation 11, side-wall spacers 33 and dummy gate 32 of the semiconductor substrate 10; then, eliminate part of the first interlayer dielectric layer 51 with chemical mechanical polishing (CMP), until the surface of the dummy gate 32 is exposed. The material of the first interlayer dielectric layer 51 can be insulating material such as silicon dioxide or silicon nitride and so on, and is formed with the way of chemical vapor deposition, in the same way, it can ensure the temperature during formation not being higher than 500 degree, and prevent the ions from diffusion.

Then, use the first interlayer dielectric layer 51 as mask, and eliminate the dummy gate 32 and the dummy gate dielectric layer 31 successively with dry etching, expose the channel region in the semiconductor substrate 10, which is, the semiconductor substrate 10 positioned under the original dummy gate dielectric layer 31.

S300: Form a short channel inhibition region 60 in the channel region of the semiconductor substrate 10;

Please refer to FIG. 10, in the step S300, form a short channel inhibition region 60 in the channel region of the semiconductor substrate 10, the short channel inhibition region 60 is formed by implanting ions, the ions implanted and the ions implanted in the source/drain region 42 are opposite type ions with each other, if the ions implanted in the source/drain region 42 are III class ions, then the ions implanted in the short channel inhibition region 60 are V class ions, vice versa. The implantation depth of the short channel inhibition region 60 is far lower than the depth of the amorphous region 20. The formed short channel inhibition region 60 can restrain the short-channel effect (SCE) well, ensure the performance of the forming semiconductor device and satisfy the requirement of keeping narrowing the feature size, the energy and the dose of the ions implanted can be selected according to preparation of different sizes semiconductor device, no limitation is made here.

For example, in the embodiment, the ions implanted of the source and drain 42 are P, the ions implanted of the short channel inhibition region 60 are BF₂, the dose can be 1E15 cm⁻², the energy can be 1 keV. To ensure that the depth of the amorphous region 20 is much larger than the source/drain region 42, the ions implanted of the amorphous region 20 are Ge, the dose can be 1E15 cm⁻², and the energy can be 50 keV.

In this embodiment, after the short channel inhibition region 60 is formed, proceed annealing process, the anneal process is used to activate the ions implanted in the source/drain extension region 41, the source/drain region 42 and the short channel inhibition region 60; besides, the annealing temperature is not higher than 600° C., it can be realized by adopting low temperature annealing ways such as low temperature microwave annealing, it can prevent the temperature from too high to lead to big scale diffusion of ions in the source/drain region, then prevent the forming semiconductor device from source/drain region current leakage, then further improve the performance of the forming semiconductor device.

S400: Form a gate structure on the channel region of the semiconductor substrate 10.

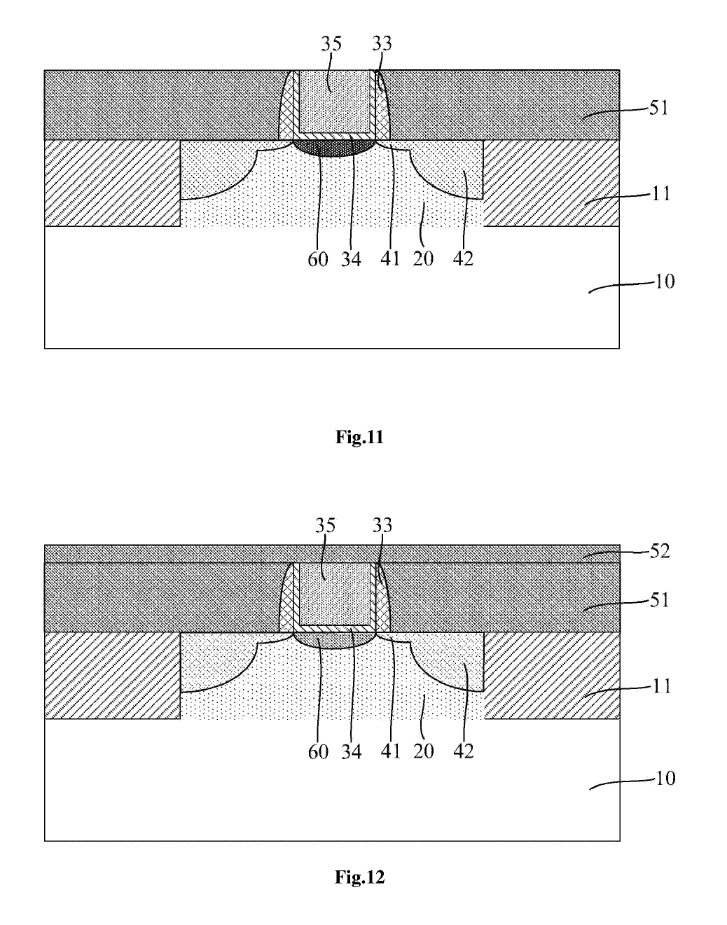

Please refer to FIG. 11, in the step S400, the renewed gate structure includes a gate dielectrics layer 34 and a gate 35 on the channel region of the semiconductor substrate 10, the material of the gate dielectrics layer 34 is material such as SiO₂ (silicon dioxide), Si₃N₄ (silicon nitride) or HfO₂ (hafnium oxide) and so on, the material of the gate 35 is conducting materials such as TiN (titanium nitride) or TaN (tantalum nitride) and so on, in the same way, the temperatures during the formation process of gate dielectrics layer 34 and gate 35 are not higher than 500 degree.

Please refer to FIG. 12, in this embodiment, after the gate structure is formed, a second interlayer dielectric layer 52 is formed on the surface of the first interlayer dielectric layer 51 and gate structure 35. The temperature forming the second interlayer dielectric layer is not high than 500° C., the material is the same with the first interlayer dielectric layer 51.

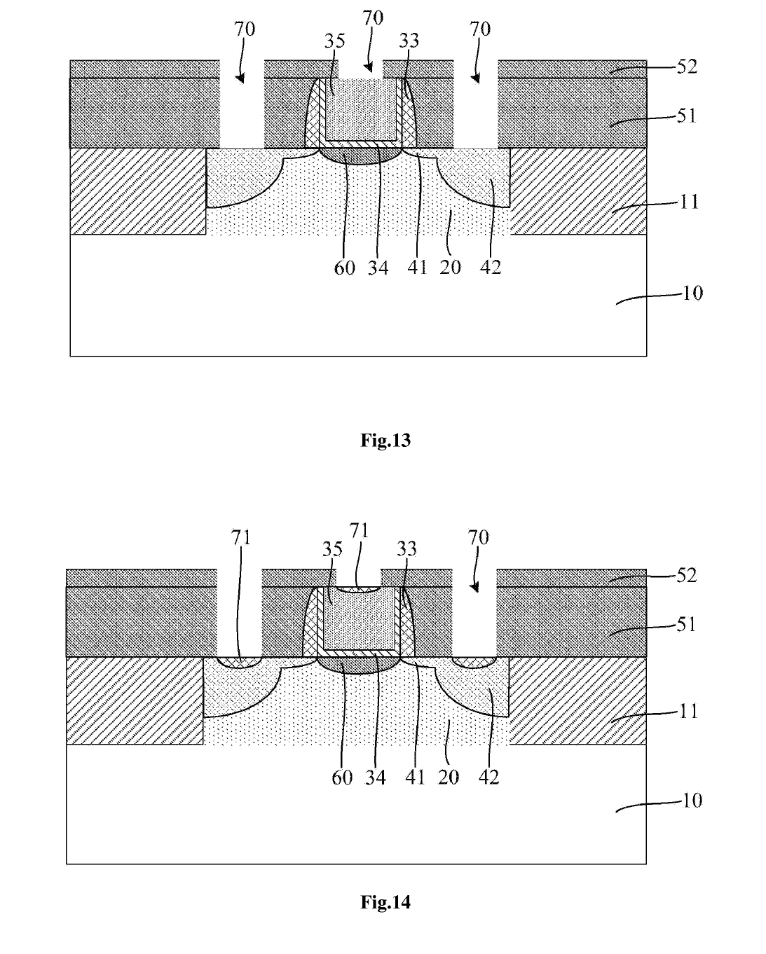

Please refer to FIG. 13, etch the second interlayer dielectric layer 52 and the first interlayer dielectric layer 51 successively and form a via hole 70, the via hole 70 exposes the surface of the source/drain region 42 and the gate 35, to be used to form a via hole line and conduct with the semiconductor device.

Please refer FIG. 14, to make the via hole formed following have a good conduction with the source/drain region 42, hence, there is a need to form a layer of self-aligned silicide 71 on the surface of the source/drain region 42 and the gate 35, and the depositional metal material needed to form the self-aligned silicide 71 is Ti (titanium), Ni (nickel) or Co (cobalt) and so on.

A second implementation manner relates to a preparation method of semiconductor device. The second implementation manner is about the same with the first implementation manner, the main differences are: in the first implementation manner, after the short channel inhibition region is formed, proceeds annealing process. But in the second implementation manner of the invention, the annealing process is proceed after the second interlayer dielectric layer is formed, it is used to activate all elements implanted, in the same way, the annealing process can be realized by adopting low temperature annealing ways such as low temperature microwave annealing and so on.

Besides, in the embodiment, the ions implanted of the source and drain 42 are P, the ions implanted of the short channel inhibition region 60 are BF₂, the dose can be 1E15 cm⁻², and the energy can be 1 keV. To ensure the depth of the amorphous region 20 is much larger than the source/drain region 42, the ions implanted of the amorphous region 20 are Ge, the dose can be 1E15 cm⁻², and the energy can be 50 keV.

The third implementation manner relates to a preparation method of semiconductor device. The Third implementation manner is about the same with the first implementation manner, the main differences are: in the first implementation manner, after the short channel inhibition region is formed, proceeds annealing process. But in the third implementation manner of the invention, the annealing process is proceed after the self-aligned silicide is formed, in the same way, the annealing process can be realized by adopting low temperature annealing ways such as low temperature microwave annealing and so on.

In this embodiment, to make the forming self-aligned silicide 71 more stable, it can be annealed after formation, in the same way, to ensure that the temperature of the annealing process is not higher than 600 degree, only one annealing process is needed to proceed after self-aligned silicide 71 is formed, it can make the self-aligned silicide 71 more stable and at the same time can activate all the elements implanted in the semiconductor device one time, the processing step is reduced, and the aim of saving cost is achieved.

Above all, in the preparation method of semiconductor device provided in the embodiments of the invention, form an amorphous region in the semiconductor substrate, then form the source/drain region of the semiconductor device in the amorphous region, the amorphous region can restrain the implanted ions diffusion in the source/drain region, so the current leakage between the source/drain region and semiconductor substrate of the semiconductor device can be well lowered; besides, after eliminating the dummy gate structure, form a short channel inhibition region in the channel region, it can restrain the short-channel effect of the semiconductor device and satisfy the requirement of keeping narrowing the feature size of the device. Further, adopting a low temperature of not higher than 600° C. to proceed annealing process can prevent big scale diffusion of ions in the source/drain region caused by too high temperature, then prevent the forming semiconductor device from source/drain region current leakage, then further improve the performance of the forming semiconductor device. Besides, adopting low temperatures of not higher than 500° C. to form the side-wall spacers, a first interlayer dielectric layer and a second interlayer dielectric layer, it is also used to prevent big scale diffusion of ions in the source/drain region caused by too high temperature, then prevent the forming semiconductor device from source/drain region leakage, then further improve the performance of the forming semiconductor device.

The above is just the preferable embodiments of the invention and is not the limitation of the invention. Variations such as equivalent replacement or modification and so on in any form to the technical proposal and technical content of the invention made by the technicians in the technical area within the scope of the technical proposal of the invention, all belong to not being disaffiliated from the content of the invention's technical proposal, still belong to the protection scope of the invention.

We claim:

1. A preparation method of semiconductor device, is characterized in that, includes the steps:
Provide a semiconductor substrate, there is an amorphous region formed in the semiconductor substrate, and there are a dummy gate structure and a source/drain region formed on the semiconductor substrate, the source/drain region is formed in the amorphous region;
Etch and eliminate the dummy gate structure and expose the channel region of the semiconductor substrate;
Form a short channel inhibition region in the channel region of the semiconductor substrate;
Form a gate structure on the channel region of the semiconductor substrate.

2. The preparation method of semiconductor device according to claim 1, is characterized in that, the amorphous region is formed by implanting ions, and the ions implanted are non-electrically active ions.

3. The preparation method of semiconductor device according to claim 1, is characterized in that, the source/drain region is formed by implanting ions, the ions implanted and the ions doped in the substrate are opposite type ions with each other, and the implantation depth of the source/drain region is smaller than the implantation depth of the amorphous region.

4. The preparation method of semiconductor device according to claim 1, is characterized in that, the short channel inhibition region is formed by implanting ions, the ions implanted and the ions doped in the substrate are same type ions with each other, and the implantation depth of the short channel inhibition region is smaller than the implantation depth of the amorphous region.

5. The preparation method of semiconductor device according to claim 1, is characterized in that, after the short channel inhibition region is formed, before the gate structure is formed, proceed annealing process, so the annealing temperature is not higher than 600° C.

6. The preparation method of semiconductor device according to claim 1, is characterized in that, the step to form the dummy gate structure includes:
Form a dummy gate dielectric layer and a dummy gate successively on the semiconductor device;
Form a source/drain extension region on the two sides of the dummy gate dielectric layer and dummy gate;
Form side-wall spacers on the two side walls of the dummy gate dielectric layer and the dummy gate.

7. The preparation method of semiconductor device according to claim 6, is characterized in that, after the source/drain region is formed, before the dummy gate structure is etched and eliminated, form a first interlayer dielectric layer on the two sides of the side-wall spacers and the surface of the semiconductor substrate.

8. The preparation method of semiconductor device according to claim 7, is characterized in that, after the gate structure is formed, a second interlayer dielectric layer is formed on the surface of the first interlayer dielectric layer and the gate structure.

9. The preparation method of semiconductor device according to claim 8, is characterized in that, the temperatures forming the side-wall spacers, the first interlayer dielectric layer and the second interlayer dielectric layer are all not high than 500° C.

10. The preparation method of semiconductor device according to claim 9, is characterized in that, after the second interlayer dielectric layer is formed, proceed annealing process, and the annealing process temperature is not higher than 600° C.

11. The preparation method of semiconductor device according to claim 7, is characterized in that, etch the second interlayer dielectric layer and the first interlayer dielectric layer to form a via hole, the via hole exposes the surface of the source/drain region and the gate.

12. The preparation method of semiconductor device according to claim 11, is characterized in that, form a self-aligned silicide on the surface of the source/drain region and the gate exposed in the via hole.

13. The preparation method of semiconductor device according to claim 12, is characterized in that, adopt annealing process after the self-aligned silicide is formed, the annealing process temperature is not higher than 600° C.
